(19) United States
(12) Patent Application Publication
(10) Pub. No.: US 2024/0128056 A1
(43) Pub. Date: Apr. 18, 2024

(54) PLASMA ETCHING APPARATUS AND OPERATING METHOD THEREOF

(71) Applicant: SAMSUNG ELECTRONICS CO., LTD., Suwon-si (KR)

(72) Inventors: Hyeontae Kim, Suwon-si (KR); Changho Kim, Suwon-si (KR); Yoonbum Nam, Suwon-si (KR); Seungbo Shim, Suwon-si (KR); Minyoung Hur, Suwon-si (KR); Kyungsun Kim, Suwon-si (KR); Juneeok Leem, Suwon-si (KR)

(73) Assignee: SAMSUNG ELECTRONICS CO., LTD., Suwon-si (KR)

(21) Appl. No.: 18/133,277

(22) Filed: Apr. 11, 2023

(30) Foreign Application Priority Data
Oct. 13, 2022 (KR) 10-2022-0131465

(51) Int. Cl. H01J 37/32

(52) U.S. Cl. CPC H01J 37/32449; H01J 37/32568; H01J 37/32816; H01J 2237/334

(57) ABSTRACT

The present disclosure provides plasma etching apparatuses and operating methods of the plasma etching apparatuses. In some embodiments, a plasma etching apparatus includes a processing chamber, a plasma source generator, a bias generator, and an acoustic wave generator. The processing chamber is configured to receive etching gas, and to etch a wafer using plasma that has been formed according to a plasma source pulse and a bias pulse. The a plasma source generator is configured to generate the plasma source pulse. The bias generator is configured to generate the bias pulse. The acoustic wave generator is configured to generate an acoustic wave having a wavefront with a first direction parallel to the wafer and to control a density of a reactive gas of the plasma.

### CROSS-REFERENCE TO RELATED APPLICATIONS

This application claims benefit of priority under 35 U.S.C. § 119 to Korean Patent Application No. 10-2022-0131465, filed on Oct. 13, 2022, in the Korean Intellectual Property Office, the disclosure of which is incorporated by reference herein in its entirety.

### BACKGROUND

### 1. Field

The present disclosure relates generally to semiconductor etching, and more particularly, to a plasma etching apparatus and an operating method thereof.

### 2. Description of Related Art

In a related semiconductor etching process, various pulse methods may be used to control an amount of ions and/or reactive gases that may be acting on a wafer in a plasma chamber. For example, high aspect ratio contact (HARC) etching may refer to a gas pulsing method in which etching and/or deposition may be repeatedly performed by adjusting an amount of etching gas introduced into a dry plasma etching chamber. HARC may be used to provide an improved etching profile of a contact hole having a high aspect ratio, when compared to other related semiconductor etching processes. A selective gas supply system may be introduced and/or gas pipes may be improved in order to better control a flow rate of the reactive etching gas in order to potentially improve a reaction speed for controlling a gas supply amount in the etching chamber. However, improvements to the reaction speed may be limited by a minimum period of a pulse (e.g., up to several seconds) due to a transient time required for stabilization of gas distribution in the etching chamber.

There exists a need for further improvements in semiconductor etching technology, as the need for improved reaction speeds may be constrained by a minimum pulse period for stabilizing gas distribution in the etching chamber. Improvements are presented herein. These improvements may also be applicable to other plasma and/or gas injection technologies and the standards that employ these technologies.

### SUMMARY

Aspects of the present disclosure provide a plasma etching apparatus, including a high-frequency gas pulse function, that may reduce a stabilization time of injection gas.

Aspects of the present disclosure provide an operating method for a plasma etching apparatus, including a high-frequency gas pulse function, that may reduce a stabilization time of injection gas.

According to an aspect of the present disclosure, a plasma etching apparatus is provided. The plasma etching apparatus includes a processing chamber, a plasma source generator, a bias generator, and an acoustic wave generator. The processing chamber is configured to receive etching gas, and to etch a wafer using plasma that has been formed according to a plasma source pulse and a bias pulse. The plasma source generator is configured to generate the plasma source pulse. The bias generator is configured to generate the bias pulse. The acoustic wave generator is configured to generate an acoustic wave having a wavefront with a first direction parallel to the wafer and to control a density of a reactive gas of the plasma.

According to an aspect of the present disclosure, an operating method of a plasma etching apparatus is provided. The operating method includes generating a plasma source pulse and a bias pulse. The operating method further includes generating, according to the plasma source pulse and the bias pulse, an acoustic wave having at least one frequency using a plurality of transducers. The operating method includes controlling a density of an etching gas using an incident wave formed by the acoustic wave that is incident to a wafer and a reflected wave that is reflected from the wafer.

According to an aspect of the present disclosure, a plasma etching apparatus is provided. The plasma etching apparatus includes a processing chamber having an upper electrode, a lower electrode, and a chuck accommodating a wafer, a plasma source generator configured to receive etching gas and to apply a plasma source pulse to the lower electrode, a bias generator configured to apply a bias pulse to the lower electrode, an acoustic wave generator configured to provide, through point wave sources disposed on the upper electrode, an acoustic wave incident to the wafer, the acoustic wave having at least one frequency, and a controller configured to control the plasma source generator, the bias generator, and the acoustic wave generator.

Additional aspects will be set forth in part in the description which follows and, in part, will be apparent from the description, or may be learned by practice of the presented embodiments.

### BRIEF DESCRIPTION OF DRAWINGS

The above and other aspects, features and advantages of certain embodiments of the present disclosure will be more apparent from the following description, taken in conjunction with the accompanying drawings, in which:

FIG. 1 is a diagram illustrating a plasma etching apparatus, according to an example embodiment;

FIG. 2 is a diagram illustrating an example of a shape of an acoustic wave, generated from an upper plane wave source that may form a standing wave inside of the plasma processing chamber 100, according to an example embodiment.

FIG. 3 is a diagram illustrating a plasma etching apparatus constituting a high-frequency planar wave source, according to an example embodiment;

FIG. 4 is a diagram illustrating a method of controlling a plasma source/bias and an on-wafer pressure, according to an example embodiment;

FIG. 5 is a diagram illustrating a method of periodically applying gas density on a surface of a wafer in a plasma etching apparatus, according to an example embodiment;

FIG. 6 is a diagram illustrating a driving situation in which a gas pressure pulse slightly shifts with respect to a plasma RF source pulse section, according to an example embodiment;

FIG. 7 is a flowchart illustrating an operating method of a plasma etching apparatus, according to an example embodiment; and

FIG. 8 is a diagram illustrating a spectrotomography plasma diagnosis apparatus, according to an example embodiment.

### DETAILED DESCRIPTION

The following description with reference to the accompanying drawings is provided to assist in a comprehensive understanding of embodiments of the present disclosure defined by the claims and their equivalents. Various specific details are included to assist in understanding, but these details are considered to be exemplary only. Therefore, those of ordinary skill in the art will recognize that various changes and modifications of the embodiments described herein can be made without departing from the scope and spirit of the disclosure. In addition, descriptions of well-known functions and structures are omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

The terms “upper,” “middle”, “lower”, etc. may be replaced with terms, such as “first,” “second,” third” to be used to describe relative positions of elements. The terms “first,” “second,” third” may be used to described various elements but the elements are not limited by the terms and a “first element” may be referred to as a “second element”. Alternatively or additionally, the terms “first”, “second”, “third”, etc. may be used to distinguish components from each other and do not limit the present disclosure. For example, the terms “first”, “second”, “third”, etc. may not necessarily involve an order or a numerical meaning of any form.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment.

As used herein, terms such as, but not limited to, “CxFy”, and the like may refer to a material made of elements included in each of the terms and is not a chemical formula representing a stoichiometric relationship.

It is to be understood that the specific order or hierarchy of blocks in the processes/flowcharts disclosed are an illustration of exemplary approaches. Based upon design preferences, it is understood that the specific order or hierarchy of blocks in the processes/flowcharts may be rearranged. Further, some blocks may be combined or omitted. The accompanying claims present elements of the various blocks in a sample order, and are not meant to be limited to the specific order or hierarchy presented.

As a general introduction to the subject matter described in more detail below, aspects described herein are directed towards a plasma etching apparatus and an operating method thereof, which by controlling plasma using an acoustic wave, may implement a high-frequency gas pulsing effect in a plasma chamber and a wafer, and may shorten a stabilization time of an injection gas. Aspects described herein are directed towards a plasma etching apparatus and an operating method thereof, which by controlling density of etching gas inside a chamber and on a surface of a wafer through the acoustic wave, may secure a high-frequency etching and/or deposition conversion function. Aspects described herein are directed towards a plasma etching apparatus and an operating method thereof, which by improving anisotropic etching through high-frequency gas pressure control and control in conjunction with an radio frequency (RF)/Bias pulse, may secure a process control knob.

Hereinafter, various embodiments of the present disclosure are described with reference to the accompanying drawings,

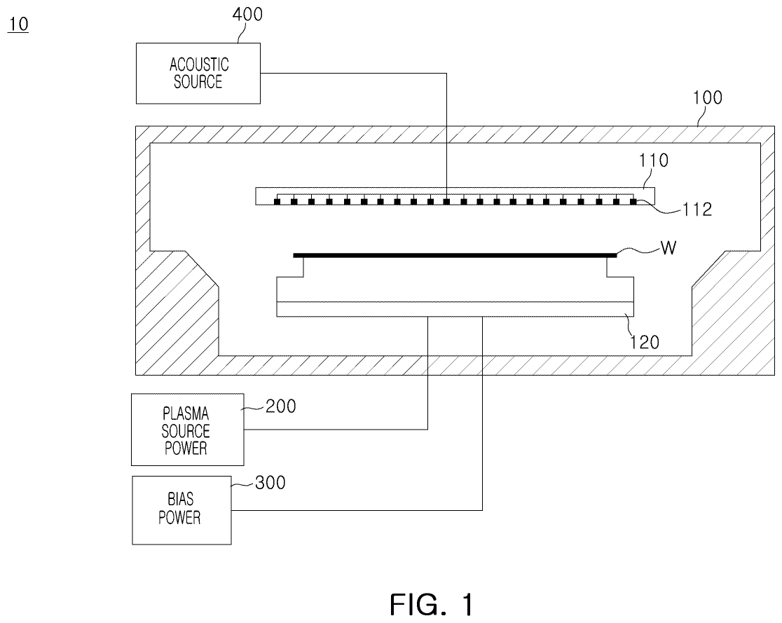

FIG. 1 is a diagram illustrating a plasma etching apparatus 10, according to an example embodiment. Referring to FIG. 1, the plasma etching apparatus 10 may include a plasma processing chamber 100, a plasma source generator 200, a bias generator 300, and an acoustic wave generator 400.

The plasma processing chamber 100 may include an upper electrode 110, a lower electrode 120, and a plasma and process gas supply unit (not shown).

The upper electrode 110 may be disposed above a vacuum container, and the lower electrode 120 may be disposed below the vacuum container. The lower electrode 120 may be disposed below the upper electrode 110. RF power (and/or pulsed power) generated from the upper electrode 110 and/or the lower electrode 120 may be coupled to plasma.

In an example embodiment, the upper electrode 110 and/or the lower electrode 120 may inductively couple power to process gases supplied to an inside of the vacuum container by the process gas supply unit. For example, RF power applied by the upper electrode 110 and/or the lower electrode 120 may be inductively coupled to process gases to form plasma in a reaction region on a semiconductor wafer substrate. Process gases supplied from a process gas supply unit may etch materials on the semiconductor wafer substrate. In an example embodiment, the process gas may include, but not be limited to, fluorocarbons (CxFy). In an example embodiment, the RF power applied from the upper electrode 110 may ignite plasma, and the RF power applied from the lower electrode 120 may control ions, radicals, and the like of the plasma.

The plasma source generator 200 may be implemented to generate a high-frequency pulse (e.g., RF pulse). In an example embodiment, the high-frequency pulse may be a single-level pulse and/or a multi-level pulse. For example, the plasma source generator 200 may generate a RF pulse using a desired phase, delay, and/or duty cycle between pulses of ultra-high frequency power generators and RF frequency power generators. However, the generation of RF pulses of the present disclosure is not limited thereto and may be generated using various methods without deviating from the scope of the present disclosure. For example, the RF pulse may be generated by at least one of an RF generator, a mid frequency (MF) generator, a high frequency (HF) generator, and a very high frequency (VHF) generator. In an example embodiment, the plasma source generator 200 may include a pulse controller (not shown). The pulse controller may be implemented to control a desired phase, delay, and/or duty cycle of the pulses of the ultra-high frequency source power generator and RF bias power generators.

The bias generator 300 may be implemented to generate a bias pulse for minimizing reflected power reflected from the plasma processing chamber 100. The bias generator 300 may substantially match an impedance of the plasma processing chamber 100 and an impedance of the plasma source generator 200 in order to minimize reflected power. In an example embodiment, a complex impedance of the plasma processing chamber 100 and a complex impedance of the bias generator 300 may be matched to approximately 50 Ohms (a). In another optional or additional example embodiment, the bias generator 300 may be implemented to substantially match an input impedance corresponding to an RF pulse to a plasma load in real time. That is, the bias generator 300 may continuously and/or periodically measure the input impedance corresponding to the RF pulse and adjust the impedance of the plasma load to substantially match the measured input impedance.

The acoustic wave generator 400 may be located at an upper end of the plasma processing chamber 100 and may be implemented to generate a planar acoustic wave. The acoustic wave generator 400 may include a planar wave source implemented to generate the acoustic wave having a largely parallel wavefront to the wafer W in order to control the density of reactive gas incident on a surface of the wafer in an electrostatic coupled plasma generator.

In an example embodiment, the planar wave source may be implemented through an arrangement of a plurality of transducers, point wave sources 112, and the like. For example, each of the plurality of transducers may convert electrical energy into wave energy (e.g., an acoustic wave). The point wave source 112 may be disposed inside the upper electrode 110. When a planar acoustic wave is incident in a direction largely perpendicular to the wafer W, a standing wave may be generated due to interference between the incident wave and the reflected wave reflected from the wafer W at a lower end thereof. The standing wave may generate periodic oscillations of gas pressure on the surface of the wafer. Consequently, periodic changes in the density of the reactive gas may be produced on the surface of the wafer by the periodic oscillations of gas pressure.

In an example embodiment, the acoustic wave generator 400 may be located at an upper end of the plasma processing chamber 100. Acoustic waves generated from the acoustic wave generator 400 may be largely perpendicularly incident on the wafer W.

The plasma etching apparatus 10, according to an example embodiment, may perform high-frequency control of etching gas pressure inside the chamber and on a surface of the wafer by forming a standing wave between a wafer and a showerhead. Alternatively or additionally, the plasma etching apparatus 10, according to an example embodiment, may perform high-frequency control driving of hydrolysis pressure in conjunction with the plasma source pulse by controlling the acoustic wave generator 400 and the bias generator 300. In an example embodiment, the plasma etching apparatus 10 may select at least one acoustic frequency to optimize a distribution of pressure inside the plasma processing chamber 100.

In a related plasma etching apparatus, a pulse interval between a plasma source and a bias may be in a range of approximately several microseconds (e.g., >10 μsec). Consequently, a need for improved process efficiency (e.g., improved reaction speeds) may be constrained by the limitation of shortening a gas pulse cycle below a minimum pulse period for stabilizing gas distribution in the etching chamber. However, in order to overcome the limitation on etching gas pulse control in related plasma etching apparatuses, the plasma etching apparatus 10, according to an example embodiment of the present disclosure, may control transport and density distribution of neutral gases and reactive radicals in an etching chamber, by receiving an acoustic wave, and propagating using gas as a medium. The plasma etching apparatus 10, according to an example embodiment, may perform high-frequency gas pressure control through a pressure standing wave inside the plasma processing chamber 100. Alternatively or additionally, the plasma etching apparatus 10 may improve deposition/etching high frequency operation and pulse operation efficiency through control in conjunction with an RF/Bias pulse. For example, the plasma etching apparatus 10, according to an example embodiment, may enable high-frequency control of an amount of radicals incident on the surface of the wafer.

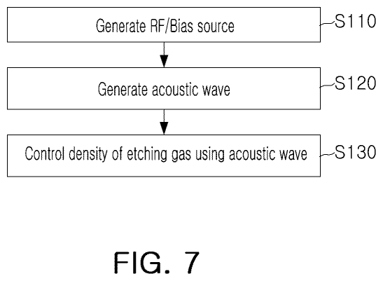

The number and arrangement of components of the plasma etching apparatus 10 shown in FIG. 1 are provided as an example. In practice, there may be additional components, fewer components, different components, or differently arranged components than those shown in FIG. 1. Furthermore, two or more components shown in FIG. 1 may be implemented within a single component, or a single component shown in FIG. 7 may be implemented as multiple, distributed components. Alternatively or additionally, a set of (one or more) components shown in FIG. 1 may be integrated with each other, and/or may be integrated with the plasma etching apparatus 10 and implemented as an integrated circuit, as software, and/or a combination of circuits and software.

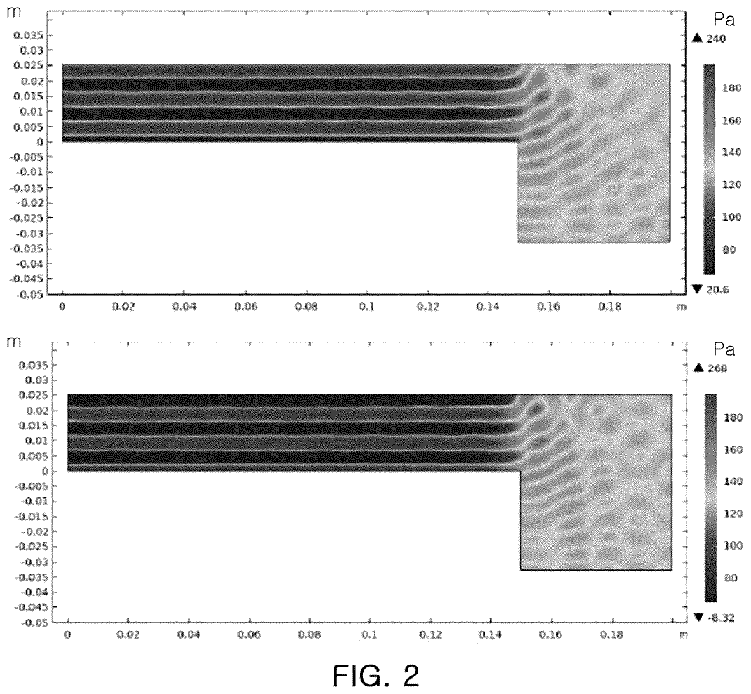

FIG. 2 is a diagram illustrating an example of a shape of an acoustic wave, generated from an upper plane wave source that may form a standing wave inside of the plasma processing chamber 100, according to an example embodiment. Referring to FIG. 2, a phenomenon is illustrated in which an acoustic wave, generated from an upper planar wave source forms a standing wave inside a chamber and gas pressure on a surface of a wafer oscillates with time.

Calculation conditions used in generating the computational analysis shown in FIG. 2, may be based on the conditions listed in Table 1 below.

TABLE 1
Calculation Conditions.

| Gas Type | Argon (Ar) | |
|---|---|---|
| Pressure | 1 | Torr |
| Gap Thickness | 2.54 | cm |
| Acoustic Frequency | 40 | kHz |

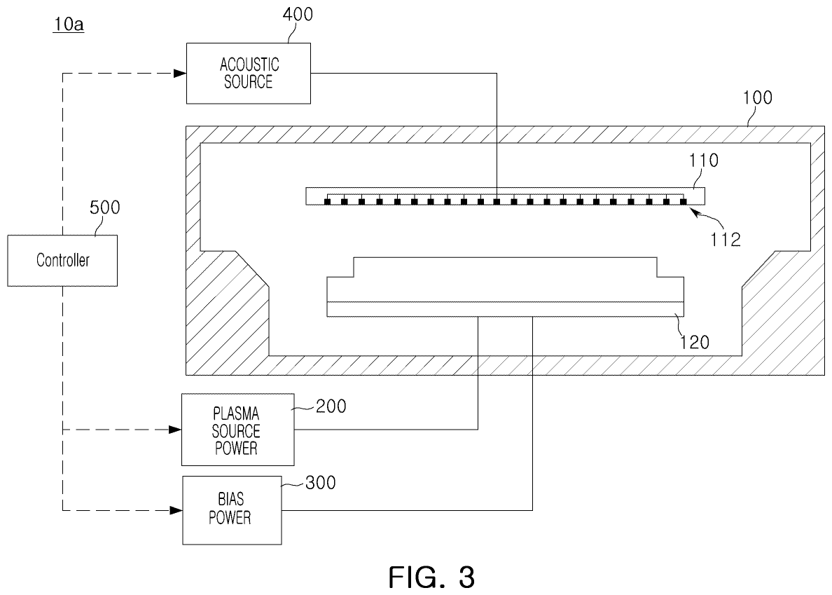

FIG. 3 is a diagram illustrating a plasma etching apparatus 10a, according to an example embodiment. Referring to FIG. 3, the plasma etching apparatus 10a may create a high-frequency plane wave source by disposing a transducer point source 112 on an upper electrode 110, according to an example embodiment.

The plasma etching apparatus 10a may include or may be similar in many respects to the plasma etching apparatus 10 described above with reference to FIG. 1 and may include additional features not mentioned above.

Referring to FIG. 3, a plasma etching apparatus 10a may include a plasma processing chamber 100, a plasma source generator 200, a bias generator 300, a acoustic wave generator 400, and a controller 500. The controller 500 may be implemented to control the plasma processing chamber 100, the plasma source generator 200, the bias generator 300, and the acoustic wave generator 400.

In an example embodiment, a plane wave having a wavefront largely parallel to the wafer may be incident into the chamber by a plurality of transducers disposed on the upper electrode 110. As shown in FIG. 3, the plasma etching apparatus 10a may include a capacitively coupled plasma (CCP)-type plasma generator (e.g., plasma source generator 200) implemented to form plasma through an RF source applied through a lower electrode 120 in a.

An acoustic wave generator 400 located at an upper end of a chamber may use an appropriate frequency for forming a standing wave in the chamber. In an example embodiment, an appropriate frequency may be determined in consideration of the type and pressure of gas and an interval between electrodes in the chamber. For example, an appropriate frequency may be selected from a frequency band of approximately 10 kHz to approximately 500 kHz.

The controller 500 may be connected (e.g., coupled) to the acoustic wave generator 400 and a high-frequency (HF)/low-frequency (LF) RF source (e.g., bias generator 300). The controller 500 may periodically drive the acoustic wave generator 400 and the HF/LF RF source 300 by generating a control signal. Such periodic driving may be continuously driven or driven in a form of On/Off, High/Low or Low/High. For example, the controller 500 may drive the acoustic wave generator 400 and the HF/LF RF source 300 based on a predetermined amount of time having elapsed. That is, the controller 500 may generate the control signal based on a determination that the predetermined amount of time has elapsed. The predetermined amount of time may be fixed (e.g., constant) and/or the predetermined amount of time may change based on several criteria such as, but not limited to, design considerations, mode/state changes, overall elapsed time, and the like. Alternatively or additionally, the generation of the control signal by the controller 500 may be event-based. For example, the controller 500 may generate the control signal in response to and/or based on one or more timers expiring, receipt of a signal, and the like.

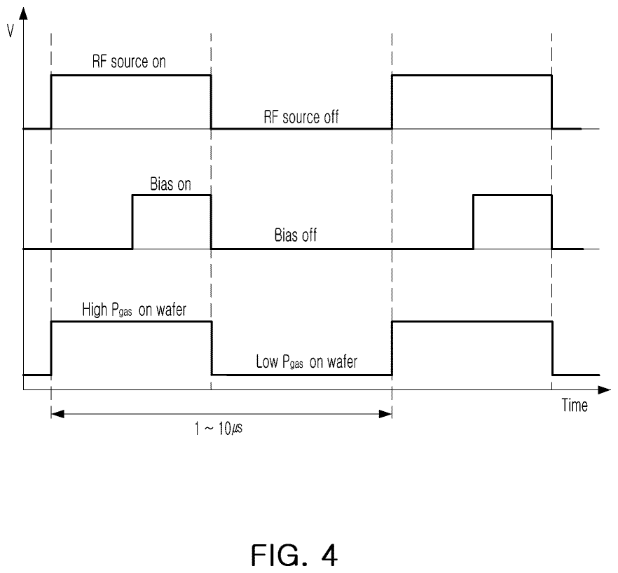

FIG. 4 is a diagram illustrating a method of controlling a plasma source/bias and on-wafer pressure through the controller 500, according to an example embodiment.

Referring to FIG. 4, on-wafer gas pressure control may be applied. The on-wafer gas pressure control may facilitate evacuation of neutral gas by applying low pressure in a by-product evacuation stage corresponding to the RF source being in an off state (e.g., RF source-off). The evacuation promotion driving may be continuously driven and/or may be driven in a form of On/Off, High/Low or Low/High pulses.

Alternatively or additionally, the on-wafer gas pressure control may be shifted and driven by a predetermined time in consideration of transport efficiency of by-products and reactive radicals. That is, it is to be understood that a driving method of on-wafer gas pressure control may be implemented in at least one of various forms.

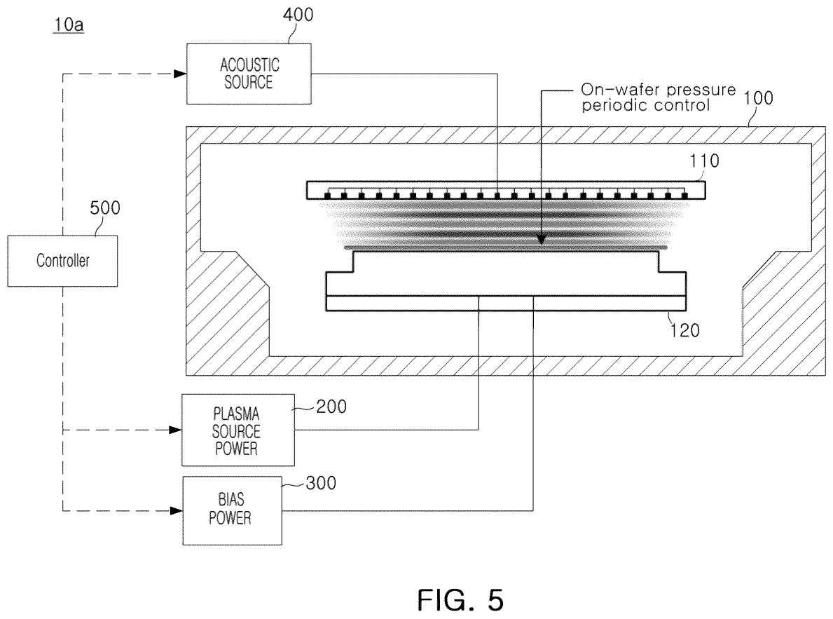

FIG. 5 is a diagram illustrating a form of periodically applying gas density on a surface of a wafer in the plasma etching apparatus 10a, according to an example embodiment. The plasma etching apparatus 10a of FIG. 5 may include or may be similar in many respects to at least one of the plasma etching apparatuses described above with reference to FIGS. 1 and 3, and may include additional features not mentioned above.

Referring to FIG. 5, an acoustic wave source having two or more frequencies may be used to control interference between an incident wave and a reflected wave in the plasma etching apparatus 10a. In an example embodiment, two or more acoustic wave source regions may be provided in a radial direction. In an optional or additional example embodiment, inductively coupled discharge, microwaves, and the like, may be used as a plasma generating source.

In an example embodiment, the controller 500 may adjust a flow rate of etching gas. For example, the controller 500 may periodically control gas pressure inside the processing chamber 100 by using an incident wave and a reflected wave of the acoustic wave. In an optional or additional example embodiment, the controller 500 may control an acoustic energy pulse in conjunction with a plasma source pulse. In another optional or additional example embodiment, the controller 500 may periodically control surface gas pressure of the wafer by using an incident wave and a reflected wave of the acoustic wave.

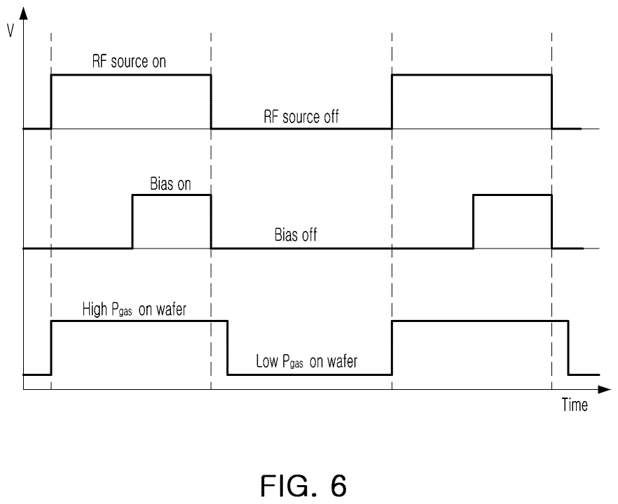

FIG. 6 is a diagram illustrating a driving situation in which a gas pressure pulse is slightly moved with respect to a plasma RF source pulse section, according to an example embodiment. Referring to FIG. 6, the gas pressure pulse may shift to change transport efficiency of by-products and radicals.

Referring to FIG. 6, a case of a 2-state pulse is shown. However, the present disclosure is not limited thereto. For example, a multi-level pulse including three or more stages may be shifted and may control gas density for periodic control of by-product evacuation and a radical reaction rate.

FIG. 7 is a flowchart illustrating an operating method of a plasma etching apparatus, according to an example embodiment. Referring to FIG. 7, an operation of a plasma etching apparatus 10 may proceed as follows.

The plasma etching apparatus 10 may generate a plasma source pulse, that is, an RF signal (operation S110). The plasma etching apparatus 10 may generate an acoustic wave (operation S120). The plasma etching apparatus 10 may control density of etching gas using the acoustic wave (operation S130).

In an example embodiment, the plasma etching apparatus 10 may adjust an inflow rate of the etching gas. For example, each of a plurality of transducers may be arranged to have intensity for controlling distribution of a plasma region. In an optional or additional example embodiment, a low-pressure reactive gas pulse may be applied when a plasma source pulse is off. Alternatively or additionally, the reactive gas pulse may be moved by a predetermined amount with respect to the plasma source pulse.

In an example embodiment, the plasma etching apparatus disclosed above may be applied to a spectrotomography plasma diagnosis device. The spectrotomography plasma diagnosis device may be implemented by adding a multi-level pulsed plasma analysis device. The spectrotomography plasma diagnosis device may be implemented to perform analysis with time resolution by synchronizing a plasma processing chamber with an RF multi-level pulse, which may be referred to as a three-dimensional (3D) chemical species distribution analysis.

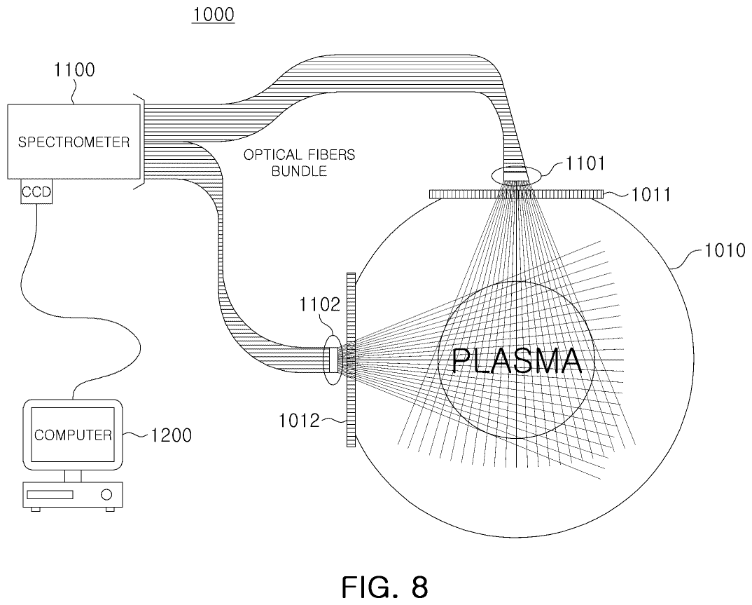

FIG. 8 is a diagram illustrating a spectrotomography plasma diagnosis apparatus, according to an example embodiment. Referring to FIG. 8, a spectrotomography plasma diagnosis apparatus 1000 may include a plasma processing chamber 1010, a spectrometer 1100, and a computing device 1200.

The spectrometer 1100 may be connected to first and second collimators and mechanical holders 1101 and 1102 through an optical channel. The first and second collimators and mechanical holders 1101 and 1102 may be disposed on windows 1011 and 1012 and disposed in different directions. The computing device 1200 may be implemented to analyze a chemical species distribution and/or a chemical species behavior using spectral data analyzed by the spectrometer 1100.

The spectrometer 1100 may be connected to the plasma processing chamber 1010 through an optical channel. The spectrometer 1100 may be implemented to analyze chemical species and/or behavior by performing spectrum analysis on each of states of a multi-level pulse (or RF power) of the plasma processing chamber 1010 in real time. For example, the spectrometer 1100 may be implemented to synchronize to a multi-level pulse and analyze a spectrum according to each of the states through an image sensor (e.g., active-pixel sensor like a complementary metal-oxide-semiconductor (CMOS) image sensor, charge-coupled device (CCD) image sensor, and the like). The states may correspond to levels of multi-level pulses. Alternatively or additionally, the spectrometer 1100 may be implemented to convert an output signal of an image sensor into logarithm. The spectrometer 1100 may be implemented to receive a trigger signal from the outside and synchronize control signals for controlling the spectrometer 1100 in response to the trigger signal.

The computing device 1200 may include at least one processor driving a program and a memory device storing the program. The processor may be implemented to perform spectral analysis related to the distribution of chemical species or the behavior of chemical species for each state of the multi-level pulse. As described above, the processor synchronizes may control signals in response to a synchronization signal corresponding to each of the states of the multi-level pulse, receive an optical signal in response to the control signals, and execute a series of instructions to perform spectral analysis on the received optical signal. The memory may be implemented to store computer readable instructions. As the instructions stored in the memory are executed in the processor, the afore-mentioned operations may be performed. The memory may be a volatile memory or non-volatile memory. The memory may include a storage device to store user data.

The example embodiments described above may be implemented with a hardware component, a software component, and/or a combination of a hardware component and a software component. For example, the device, method, and component described in the example embodiments may be implemented using one or more general-purpose computers and special purpose computers such as, processors, controllers, arithmetic logic units (ALUs), digital signal processors, microcomputers, field programmable gate arrays (FPGAs), programmable logic units (PLUs), microprocessors, or any other device capable of executing and responding to instructions. The processing device may execute an operating System (OS) and one or more software applications running on the operating system.

In addition, the processing device may also access, store, manipulate, process, and generate data in response to execution of the software. For convenience of understanding, it may be seen that, although one processing device is sometimes described as being used, one of ordinary skill in the art will recognize that the processing device may include a plurality of processing elements and/or a plurality of types of processing elements. For example, the processing device may include a plurality of processors or one processor and one controller. Other co-processor configurations are also possible, such as a Parallel Processor.

The software may include a computer program, code, instructions, or a combination of one or more thereof, and configure the processing device to operate as desired or command the processing device independently or collectively. Software and/or data may be permanently or temporarily embodied on any type of machine, component, physical device, virtual equipment, computer storage medium or device, or transmitted signal waves, to be interpreted by or provide instructions or data to the processing device. The software may be distributed over a computer system connected via a network, and stored or executed in a distributed manner. The software and data may be stored in one or more computer-readable recording media.

The present disclosure provides a system in which an acoustic wave generator is applied to a plasma processing chamber, wherein in a system in which pulse driving is used, such as in an etching process, an acoustic wave generator in which a flow rate control of etching gas is applied, and having at least one frequency type is included, and a controller for periodically controlling gas pressure in a chamber using acoustic waves and reflected waves incident into the chamber may be included.

The present disclosure provides a system in which an acoustic wave generator is applied to a plasma processing chamber, wherein in a system in which pulse driving is used, such as in an etching process, a sound energy pulse control drive in which a flow rate of etching gas is applied, and linked to an RF output is included, and a controller for periodically controlling gas pressure in a chamber using acoustic waves and reflected waves incident into the chamber may be included.

The present disclosure provides a system in which an acoustic wave generator is applied to a plasma processing chamber, wherein in a system in which pulse driving is used, such as in an etching process, a sound energy pulse control drive in which a flow rate of etching gas is applied, and linked to an RF output is included, and a controller for periodically controlling gas pressure in a chamber using acoustic waves and reflected waves incident into the chamber may be included.

According to the present disclosure, it may be possible to secure a high-frequency etching/deposition switching function by controlling density of etching gas inside a chamber using an acoustic wave. In an example embodiment, it may be possible to improve a degree of anisotropic etching and to secure a process control knob by adjusting the high-frequency density of the etching gas on a surface of the wafer. According to the present disclosure, using acoustic waves and internal reflected waves incident on the chamber, etching gas pressure/density control and driving in conjunction with an RF output may be performed.

The present disclosure provides a system in which an acoustic wave generator, propagating using etching gas as a medium in a plasma processing chamber, is applied to a plasma processing chamber, wherein an upper acoustic wave generator having at least one frequency type, and using acoustic waves may be included, and a controller periodically controlling gas pressure inside the chamber by using the acoustic waves incident into the chamber and reflected waves may be included. In an example embodiment, the controller may include acoustic energy pulse control actuation in conjunction with RF and Bias generators. In an example embodiment, in pulse control driving, a composite pulse in conjunction with an RF pulse and a bias pulse may be variably driven in the middle of a process. In an example embodiment, a flow rate of the etching gas may be controlled through the gas flow control device in pulse control driving. In an example embodiment, an acoustic frequency may be selected to adjust pressure inside the chamber or pressure on a surface of the wafer in pulse control driving. In an example embodiment, an arrangement of an acoustic wave generator may be implemented to have intensity for controlling distribution of a plasma region.

As set forth above, according to an example embodiment of the present disclosure, in a plasma etching apparatus and an operating method thereof, by controlling plasma using an acoustic wave, a high-frequency gas pulsing effect may be implemented in a plasma chamber and a wafer, and a stabilization time of injection gas may be shortened.

Alternatively or additionally, in the plasma etching apparatus and the operating method thereof, according to an example embodiment, by controlling density of etching gas inside a chamber and on a surface of the wafer through an acoustic wave, a high-frequency etching/deposition conversion function may be secured.

According to an example embodiment, in the plasma etching apparatus and the operating method thereof, by improving high-frequency gas pressure control and control in conjunction with an RF/Bias pulse, a process control knob may be secured.

The above-described content of the present disclosure may described specific example embodiments for carrying out the present disclosure. However, it is to be understood that the present disclosure may include technical ideas, which are abstract and conceptual ideas that may be used as technology in the future, as well as concrete and practically usable means themselves.

The various advantages and effects of the present disclosure are not limited to the above description, and may be more easily understood in the course of describing the specific embodiments of the present disclosure. While example embodiments have been shown and described above, it will be apparent to those skilled in the art that modifications and variations could be made without departing from the scope of the present disclosure, as defined by the appended claims.

What is claimed is:

1. A plasma etching apparatus, comprising:
a processing chamber configured to receive etching gas, and to etch a wafer using plasma that has been formed according to a plasma source pulse and a bias pulse;
a plasma source generator configured to generate the plasma source pulse;
a bias generator configured to generate the bias pulse; and
an acoustic wave generator configured to generate an acoustic wave having a wavefront with a first direction parallel to the wafer and to control a density of a reactive gas of the plasma.

2. The plasma etching apparatus of claim 1, wherein the acoustic wave generator is disposed in an upper end portion of the processing chamber.

3. The plasma etching apparatus of claim 1, wherein the acoustic wave generator comprises a plurality of transducers configured to generate the acoustic wave.

4. The plasma etching apparatus of claim 3, wherein:
the processing chamber comprises an upper electrode comprising a plurality of point wave sources, and
each transducer of the plurality of transducers is disposed in a corresponding point wave source of the upper electrode of the processing chamber.

5. The plasma etching apparatus of claim 1, wherein:
the acoustic wave is incident to the wafer in a second direction perpendicular to the wafer, and
the acoustic wave forms a standing wave by an interference action of a reflected wave that is reflected from the wafer.

6. The plasma etching apparatus of claim 5, wherein the standing wave generates periodic oscillations of gas pressure on a surface of the wafer thereby causing periodic changes in the density of the reactive gas.

7. The plasma etching apparatus of claim 1, further comprising:
a controller configured to control the plasma source generator, the bias generator, and the acoustic wave generator,
wherein the acoustic wave has at least one frequency.

8. The plasma etching apparatus of claim 7, wherein:
the at least one frequency of the acoustic wave comprises at least two frequencies, and
the controller is further configured to adjust interference between an incident wave and a reflected wave of the acoustic wave, using the at least two frequencies of the acoustic wave.

9. The plasma etching apparatus of claim 7, wherein the controller is further configured to apply a low-pressure gas pressure pulse when the plasma source pulse is in a low state.

10. The plasma etching apparatus of claim 7, wherein the controller is further configured to move a gas pressure pulse by a predetermined interval with respect to the plasma source pulse.

11. An operating method of a plasma etching apparatus, comprising:
generating a plasma source pulse and a bias pulse;
generating, according to the plasma source pulse and the bias pulse, an acoustic wave having at least one frequency using a plurality of transducers; and
controlling a density of an etching gas using an incident wave formed by the acoustic wave that is incident to a wafer and a reflected wave that is reflected from the wafer.

12. The operating method of claim 11, further comprising:
adjusting an inflow rate of the etching gas.

13. The operating method of claim 11, further comprising:
controlling distribution of a plasma region using the plurality of transducers.

14. The operating method of claim 11, further comprising:
applying a low-pressure reactive gas pulse when the plasma source pulse is in a low state.

15. The operating method of claim 14, further comprising:
moving the low-pressure reactive gas pulse by a predetermined amount with respect to the plasma source pulse.

16. A plasma etching apparatus, comprising:
a processing chamber having an upper electrode, a lower electrode, and a chuck accommodating a wafer;
a plasma source generator configured to receive etching gas and to apply a plasma source pulse to the lower electrode;
a bias generator configured to apply a bias pulse to the lower electrode;
an acoustic wave generator configured to provide, through point wave sources disposed on the upper electrode, an acoustic wave incident to the wafer, the acoustic wave having at least one frequency; and
a controller configured to control the plasma source generator, the bias generator, and the acoustic wave generator.

17. The plasma etching apparatus of claim 16, wherein the controller is further configured to control a flow rate of the etching gas.

18. The plasma etching apparatus of claim 16, wherein the controller is further configured to periodically control internal gas pressure of the processing chamber using an incident wave and a reflected wave of the acoustic wave.

19. The plasma etching apparatus of claim 16, wherein the controller is further configured to control an acoustic energy pulse associated with the plasma source pulse.

20. The plasma etching apparatus of claim 16, wherein the controller is further configured to periodically control surface gas pressure of the wafer using an incident wave and a reflected wave of the acoustic wave.
